(19) United States
(12) Patent Application Publication
(10) Pub. No.: US 2014/0273328 A1
(43) Pub. Date: Sep. 18, 2014

(54) SEMICONDUCTOR ELEMENT PRODUCING METHOD

(71) Applicant: Panasonic Corporation, Osaka (JP)

(72) Inventors: Akihiko Sagara, Hyogo (JP); Satoshi Shibata, Osaka (JP)

(21) Appl. No.: 14/348,787

(22) PCT Filed: May 16, 2013
(86) PCT No.: PCT/JP2013/003114

§ 371 Date: Mar. 31, 2014

(30) Foreign Application Priority Data
Aug. 28, 2012 (JP) 2012-187185

(51) Int. Cl. H01L 31/18; H01L 21/324; H01L 21/265

(52) U.S. Cl. CPC H01L 31/1864; H01L 21/26506; H01L 31/1804; H01L 21/324
USPC 438/57; 438/530

(57) ABSTRACT

A semiconductor device is fabricated by performing the steps of: (a) implanting dopant ions into a semiconductor base member, which is made of single-crystal Si, to define at least one of an n-type region and a p-type region in the semiconductor base member; (b) conducting a first heat treatment on the semiconductor base member, in which the n-type or p-type region has been defined, at a temperature rise/fall rate of 40° C./sec or more and with the highest temperature to reach set within the range of 1000° C. to 1200° C.; and (c) conducting a second heat treatment on the semiconductor base member, which has gone through the first heat treatment, at a lower temperature rise/fall rate than in the first heat treatment.

### TECHNICAL FIELD

The present disclosure relates to a method for fabricating a semiconductor device.

### BACKGROUND ART

In this description, the “semiconductor device” refers herein to an electronic device, at least a part of which is a semiconductor portion. The semiconductor device is typically an integrated circuit component or solid-state image sensor including a single-crystal semiconductor layer or a single-crystal semiconductor substrate. In this description, a “semiconductor layer” and a “semiconductor substrate” will be sometimes collectively referred to herein as a “semiconductor base member”. In the following description, a solid-state image sensor will be described as an example of a conventional semiconductor device.

As representative solid-state image sensors, silicon (Si)-based CCD (charge-coupled device) image sensors and CMOS (complementary metal oxide semiconductor) image sensors have been developed.

In these image sensors, their photoelectrically converting section and charge transfer section which play an important role for them are formed by implanting ions of some dopant such as boron (B) that is a p-type dopant or arsenic (As) or phosphorus (P) that is an n-type dopant into either an Si substrate or an Si thin film which has grown epitaxially on an Si substrate. The dopant ions to be implanted during this process step collide against, and are physically implanted into, the substrate or the thin film with a high acceleration voltage. That is why in the substrate or thin film that has just been subjected to the implantation process step, its crystals are significantly disturbed and the dopant introduced has not been activated sufficiently yet. In addition, there are a lot of defects there.

For that reason, in order to activate the dopant and reduced the defects, a heat treatment is carried out after the ion implantation.

To activate the dopant sufficiently, the highest temperature to reach during the heat treatment needs to be set to be equal to or higher than 1000° C. However, if the thermal budget increases as the highest temperature to reach rises, the dopant will diffuse more and more under the heat. As a result, the quantity of light converted photoelectrically and the quantity of electric charges transferred will decrease to have a negative impact on the characteristic of the device.

On top of that, it becomes more difficult to further cut down the size of the device, which is also a problem.

Thus, to overcome these problems, instead of the conventional long annealing using an electric furnace (FA), a high-temperature short annealing process, in which the temperature can be raised and lowered quickly by rapid thermal annealing (RTA), has been adopted as a heat treatment method by which the dopant can be activated sufficiently and yet the diffusion can be minimized, as disclosed in Patent Document No. 1.

Also, to further shorten the annealing process time, a laser annealing (LSA) process as disclosed in Patent Document No. 2 and a flash lamp annealing (FLA) process as disclosed in Patent Document No. 3 have also been proposed recently.

However, the results of the researches disclosed in Non-Patent Document No. 1 revealed just lately that since the high-temperature short annealing process such as the RTA process requires to raise and lower the temperature quickly (which involves rapid heating and cooling), the defects cannot be repaired sufficiently or even new defects may be created as well.

### CITATION LIST

### Patent Literature

Patent Document No. 1: Japanese Laid-Open Patent Publication No. 2001-291677
Patent Document No. 2: Japanese Laid-Open Patent Publication No. 2007-281318
Patent Document No. 3: Japanese Laid-Open Patent Publication No. 2008-098640

### Non-Patent Literature

Non-Patent Document No. 1: A. Sagara, M. Hiraiwa, A. Uedono and S. Shibata, “Detection and Characterization of Residual Damage in Low-Dose Arsenic Implanted Silicon after High-Temperature Annealing”, IEEE. Proc. the 12th International Workshop on Junction Technology 2012, pp. 81-84.

### SUMMARY OF INVENTION

### Technical Problem

Thus, to overcome these problems, the present disclosure provides a heat treatment method by which the dopant implanted can be activated sufficiently with its diffusion minimized and the crystal imperfections created during the dopant implantation can also be repaired.

### Solution to Problem

To overcome these problems, a method for fabricating a semiconductor device according to the present disclosure includes the steps of:

(a) implanting dopant ions into a semiconductor base member, which is made of single-crystal Si, to define at least one of an n-type region and a p-type region in the semiconductor base member;

(b) conducting a first heat treatment on the semiconductor base member, in which the n-type or p-type region has been defined, at a temperature rise/fall rate of 40° C./sec or more and with the highest temperature to reach set within the range of 1000° C. to 1200° C.; and

(c) conducting a second heat treatment on the semiconductor base member, which has gone through the first heat treatment, at a lower temperature rise/fall rate than in the first heat treatment and at a heat treatment temperature of 700° C. to 750° C.

### Advantageous Effects of Invention

According to the present disclosure, even though the same heat treatment system as the one that has been used in a conventional semiconductor device manufacturing process is used, a dopant implanted into a semiconductor device can be activated sufficiently with its diffusion minimized, and the crystal imperfections created during the dopant implantation can also be repaired. That is why by applying this method to a solid-state image sensor, a solid-state image sensor with excellent sensitivity characteristic, charge transfer efficiency and image quality is realized easily at a reduced cost.

### BRIEF DESCRIPTION OF DRAWINGS

FIG. 1 A cross-sectional view illustrating a CCD image sensor which may be fabricated by a semiconductor device manufacturing process according to an embodiment of the present disclosure.

FIG. 2 A flowchart showing the procedure in which a semiconductor device is fabricated according to an embodiment of the present disclosure.

FIG. 3 A cross-sectional view of an Si substrate which has been made by a method of forming a charge transfer section.

FIG. 4 A graph showing a difference in the quantities of defects in a wafer by comparing CL spectra to each other.

FIG. 5 A graph showing how the TO line emission intensity depends on the temperature of an additional (second) heat treatment.

FIG. 6 A graph showing how much the lifetime of effective carriers can be extended by the second heat treatment (FA).

FIG. 7 A graph showing how the profiles of As and B implanted change before and after the second heat treatment (FA at 700° C.).

FIG. 8 A graph showing how the profiles of As and B implanted change before and after the second heat treatment (FA at 900° C.).

### DESCRIPTION OF EMBODIMENTS

The defects created by the RTA are very minor tiny defects that can only be detected by comparing the degrees of crystallinity by cathodoluminescence (CL) method or carrier life measuring method. Nevertheless, those defects can still be a factor for scattering electrons, and therefore, could be fatal defects for a solid-state image sensor which transfers electrons directly. In fact, if the dopant is activated by RTA, the sensitivity characteristic, charge transfer efficiency and image quality of a solid-state image sensor will deteriorate.

To reduce such minor tiny defects by activating the dopant which has been implanted into either a single-crystal semiconductor substrate or a semiconductor layer that has grown epitaxially on the single-crystal substrate, the temperature rise/fall rate during the heat treatment to be conducted after dopant ions have been implanted should be decreased so as to heat and cool the semiconductor substrate or layer gradually. However, if the temperature rise/fall rate is simply decreased, then it will take a longer time to carry out the heat treatment process, the thermal budget will increase, and therefore, the dopant will diffuse. For that reason, it has been very difficult to get a heat treatment done while activating the dopant sufficiently with its diffusion minimized and yet repairing the crystal imperfections.

A method for fabricating a semiconductor device according to a non-limiting exemplary embodiment of the present disclosure includes the steps of: (a) implanting dopant ions into a semiconductor base member, which is made of single-crystal Si, to define at least one of an n-type region and a p-type region in the semiconductor base member; (b) conducting a first heat treatment on the semiconductor base member, in which the n-type or p-type region has been defined, at a temperature rise/fall rate of 40° C./sec or more and with the highest temperature to reach set within the range of 1000° C. to 1200° C.; and (c) conducting a second heat treatment on the semiconductor base member, which has gone through the first heat treatment, at a lower temperature rise/fall rate than in the first heat treatment and at a heat treatment temperature of 700° C. to 750° C.

By adopting a method for fabricating a semiconductor device according to this embodiment, the dopant can be activated with its diffusion minimized and the crystal imperfections can also be repaired.

Next, it will be described with reference to FIG. 2 how to fabricate a semiconductor device according to an embodiment of the present disclosure. As the semiconductor base member, a base member, at least a portion of which is a single-crystal semiconductor layer that is made mostly of Si, is used. Specifically, either an Si substrate or a base member in which a single-crystal thin film has been formed on an Si substrate is used.

In the step (a), ions of an n-type or p-type dopant are implanted into either the Si substrate or the Si thin film that has been formed on the Si substrate. In this manner, an n-type or p-type region is defined in the semiconductor base member. The ions of the p-type dopant may be boron (B) ions, for example. The ions of the n-type dopant may be arsenic (As) or phosphorus (P) ions, for example.

Next, in the first heat treatment process step (b), a high-temperature short annealing process such as an RTA is carried out, thereby activating the dopant implanted with its diffusion minimized. The highest temperature to reach during this first heat treatment process step (b) falls within the range of 1000° C. to 1200° C. The temperature rise/fall rate is equal to or higher than 40° C./sec. The ambient gas for use in this first heat treatment process step (b) may be nitrogen (N₂) gas, for example.

If only such a high-temperature short annealing process such as an RTA process is carried out, then some crystal imperfections will be left. Thus, in the second heat treatment process step (c), an annealing process, of which the temperature rise/fall rate is lower than that of the high-temperature short annealing process such as the RTA process, is carried out at a lower temperature, thereby reducing the defects with the diffusion of the implanted dopant still minimized. Such a second heat treatment process step may be carried out as a furnace annealing (FA) process using an electric furnace, for example. In this second heat treatment process step, the temperature rise/fall rate is equal to or lower than 40° C./sec and may typically be set within the range if 4° C./sec to 10° C./min. The ambient gas for use in this second heat treatment process step (c) may be nitrogen (N₂) gas, for example, as in the first heat treatment process step (b).

The dopant ions implanted in the first heat treatment process step (a) may be only n-type dopant ions, only p-type dopant ions, or both of the n-type and p-type dopant ions. That is to say, the first and second heat treatment process steps may be carried out either after only n-type or p-type dopant ions have been implanted or after both of n-type and p-type dopant ions have been implanted. Optionally, the first and second heat treatment process steps may be performed repeatedly a number of times. For example, p-type dopant ions may be implanted first, the first and second heat treatment process steps may be performed next, n-type dopant ions may be implanted after that, and then the first and second heat treatment process steps may be performed once again.

It should be noted that the highest temperature to reach during the second heat treatment process step (c) is suitably within the range of 700° C. to 750° C. as will be described later.

A method for fabricating a semiconductor device according to this embodiment can used effectively to make a semiconductor device with a p-type or n-type region that has been formed by ion implantation. This method can also be used to make a device with a pn junction.

Examples of semiconductor devices include solid-state image sensors and MOS transistors. The solid-state image sensors include CCD image sensors and CMOS image sensors. The method of the present disclosure is applicable particularly effectively to a device, of which the device characteristic will be seriously affected by minor tiny defects to be left after dopant ions have been implanted, among various kinds of semiconductor devices. A CCD image sensor is a typical example of such a semiconductor device.

That is why in the following description, a CCD image sensor will be used as an exemplary semiconductor device. The COD image sensor of this embodiment is based on Si.

The CCD image sensor shown in FIG. 1 includes an Si substrate 1, an Si epitaxially grown film 2 which has been formed on the Si substrate 1, and a gate insulating film 3 of silicon dioxide (SiO₂). A photoelectrically converting section 4 which converts light into signal charges and a charge transfer section 5 which needs to be used to transfer the signal charges have also been formed. Furthermore, a charge extracting section 7 which extracts the signal charges that have been generated in a device isolation section 6 and the photoelectrically converting section 4 to the charge transfer section 5 is arranged between the photoelectrically converting section 4 and the charge transfer section 5.

The photoelectrically converting section 4 is comprised of an n-type dopant implanted layer 4(n) and a p-type dopant implanted layer 4(p). Likewise, the charge transfer section 5 is also comprised of an n-type dopant implanted layer 5(n) and a p-type dopant implanted layer 5(p).

Furthermore, a transfer electrode 8 has been formed selectively over the charge transfer section 5 with the gate insulating film 3 interposed between them. And on the transfer electrode 8, an interlevel dielectric film 9 and an opaque film 10 to prevent leakage of light have been stacked to cover all of these members.

Furthermore, a planarizing film 11 has been formed to iron out the level difference between the regions with the transfer electrodes 8 and the regions without the transfer electrodes 8. A color filter 12 has been formed on the planarizing film 11. And top lenses 13 are arranged on the color filter 12 to condense incoming light onto the photoelectrically converting section 4.

Next, it will be described generally how to make a CCD image sensor with such a configuration.

First of all, as shown in FIG. 1, an n-type Si epitaxial grown film 2 is formed on an Si substrate which is an n-type semiconductor substrate. Next, a gate insulating film 3 is formed thereon by thermally oxidizing its surface.

Subsequently, the Si epitaxial grown film 2 is implanted with ions of a p-type dopant and thermally treated, and then selectively implanted with ions of an n-type dopant and subjected to the first and second heat treatments, thereby forming an n-type dopant implanted layer 4(n) to be a photoelectrically converting section 4.

Thereafter, ions of an n-type dopant and ions of a p-type dopant are implanted selectively and the first and second heat treatments are carried out, thereby forming an n-type dopant implanted layer 5(n) and a p-type dopant implanted layer 5(p) to be a charge transfer section 5. Furthermore, ions of a p-type dopant are selectively implanted to between the photoelectrically converting section 4 and the charge transfer section 5 and a heat treatment is carried out, thereby forming a device isolation region 6 and a charge extracting section 7.

After that, a conductive material film is deposited on the gate insulating film 3 and then dry-etched using a photoresist pattern (not shown) as a mask, thereby removing the conductive material film and the gate insulating film 3 to form a transfer electrode 8 which also functions as an extracting electrode and to cut a light-receiving hole through the region to be the photoelectrically converting section 4.

Next, using a photoresist pattern (not shown) and the transfer electrode 8 as a mask, ions of a p-type dopant are implanted and a heat treatment is carried out, thereby forming a p-type dopant implanted layer 4(p) to be the photoelectrically converting section 4.

Subsequently, an opaque film 10 of tungsten, for example, is formed over the transfer electrode 8 with an interlevel dielectric film 9 interposed between them. Then, a BPSG (boron phosphorus silicate glass) film is deposited to form a color filter 12 and then a silicon nitride (SiN) film is deposited to form top lenses 13.

### EXAMPLES

Hereinafter, it will be described by way of illustrative example how to implant dopant ions and then carry out a heat treatment in order to form a charge transfer section for a CCD image sensor.

First of all, the structure of a charge transfer section which was used in this example is shown in FIG. 3.

A sample semiconductor device to be fabricated in this example has a structure in which an SiO₂ film 15 has been formed on the surface of an Si substrate 14 at least in the region shown in FIG. 3. And the Si substrate 14 includes an n-type dopant implanted layer 16 and a p-type dopant implanted layer 17 which have been formed in this order under the surface of the substrate 14. In the Si substrate 14, ions of As have been implanted into the n-type dopant implanted layer 16 and ions of B have been implanted into the p-type dopant implanted layer 17, thereby defining a pn junction between them.

It should be noted that the n-type and p-type dopant implanted layers 16 and 17 of this example respectively correspond to the n-type and p-type regions 4(n) and 4(p) of the charge transfer section shown in FIG. 1.

In this example, a general Si substrate 14 for use to make a large-scale integrated circuit (LSI: large scale integration) was provided as a semiconductor base member. At this stage (i.e., before the ion implantation process), neither the n-type dopant implanted layer 16 nor the p-type dopant implanted layer 17 had been formed yet.

Next, an SiO₂ film 15 was formed on the Si substrate.

The SiO₂ film 15 may be formed under the same condition as the one for forming a thermal oxide film by a general silicon process. In this example, the surface of the Si substrate 14 was thermally treated at 900° C. for 55 minutes and then at 1000° C. for 20 minutes, thereby forming an SiO₂ film 15 to a thickness of 43 nm.

After that, to form a charge transfer section by defining a pn junction in the Si substrate 14, dopants were implanted. In this example, As which is generally used in performing a dopant introducing process step was selected to form an n-type dopant implanted layer. In this case, the implant energy (acceleration energy) of As was set to be 150 keV and the implant dose was set to be 1×10¹³ cm⁻².

Meanwhile, B which is generally used in performing a dopant introducing process step was selected to form a p-type dopant implanted layer. In this case, the implant energy of B was set to be 250 keV and 400 keV and the implant dose was set to be 1×10¹² cm⁻².

As the dopants to implant, P, antimony (Sb) or indium (In), which can contribute to forming a pn junction, may also be used. Optionally, carbon (C), germanium (Ge) or any other suitable dopant may be implanted as additional dopants as well. The implant energy and implant dose do not have to be the ones used in this example, neither.

Subsequently, an RTA process was carried out as the first heat treatment process at a temperature rise/fall rate of 40° C./sec so that a highest temperature to reach of 1100° C. was maintained for 30 seconds. In this process step, the highest temperature to reach should be high enough to activate As and B sufficiently but should be lower than the melting point of the Si substrate, and may fall within the range of 1000° C. to 1200° C. Also, the amount of time for maintaining the highest temperature to reach is defined to be short enough to avoid diffusing the dopants (e.g., which may be more than 0 seconds and equal to or shorter than 60 seconds).

The results of low-temperature (15K) cathode-luminescence (CL) measurement which was carried out on a sample thus obtained are indicated by the solid curve in FIG. 4. For the purpose of comparison, the low-temperature CL spectrum of a sample in which only an SiO₂ film was deposited to a thickness of 43 nm on an Si substrate (and which is called “untreated sample” as a comparative example) is also indicated by the dotted curve in FIG. 4.

As can be seen from FIG. 4, only a TO line, which is a band-edge emission of Si, was observed in both of these spectra, and no emission lines resulting from point defects were observed. However, it can be seen that except in the process step (c), the emission intensity of the TO line observed in the sample that was subjected to both of the dopant implantation and the RTA (as indicated by the solid curve) was lower than that of the TO line observed in the comparative example that was subjected to neither the dopant implantation nor the RTA (as indicated by the dotted curve).

This indicates that in the sample that was subjected to the dopant implantation and the RTA, there were defects that would cause a decrease in the emission intensity of the TO line.

Also, since there is an inverse correlation between the emission intensity of the TO line and the quantity of residual defects, the quantities of defects can be compared to each other based on the degrees of recovery of the emission intensity of the TO line.

Thus, in order to reduce the number of defects in that sample that was subjected to the dopant implantation and the RTA process (i.e., the untreated sample as a comparative example), an FA process was carried out as the second heat treatment process (c) using a large electric furnace. This second heat treatment was carried out at a temperature rise/fall rate of 7° C./min so that the highest temperature to reach, which was set to be any of the six levels of 300, 400, 500, 600, 700, 800 and 900° C., would be maintained for 60 minutes.

The samples thus obtained were subjected to a low-temperature CL measurement. As a result, in samples which were subjected to the second heat treatment at temperatures of 500° C. and 600° C., respectively, emission lines resulting from point defects were observed. On the other hand, in samples which were subjected to the second heat treatment at temperatures of 300° C., 400° C., 700° C., 800° C. and 900° C., no emissions resulting from point defects were observed but only a TO line was observed. Thus, the relations between the TO line emission intensities of those samples and the temperatures of the second heat treatment (i.e., the temperatures of the additional heat treatment) are shown in FIG. 5. For the purpose of comparison, the TO line emission intensity of a sample that was not subjected to the second heat treatment process step (c) is indicated by the open circle and the dotted line in FIG. 5.

As can be seen from FIG. 5, as the temperature of the additional heat treatment rises, the TO line emission intensity increases and the quantity of defects decreases. Particularly if the temperature of the additional heat treatment is equal to or higher than 700° C., the TO line emission intensity increases steeply and then tends to be saturated.

A photoexcited free carrier measurement was carried out on the samples that were subjected to an additional heat treatment at temperatures of 700° C., 800° C. and 900° C., respectively, in the process step (c) to estimate the lifetime of effective minority carriers. The results are shown in FIG. 6. For the purpose of comparison, the lifetime of effective minority carriers in the sample that was not subjected to the additional heat treatment by omitting the process step (c) is indicated by the open circle in FIG. 6.

As can be seen from FIG. 6, if the temperature of the additional heat treatment was equal to or higher than 700° C., the lifetime of effective minority carriers increased. And these results also revealed that the quantity of defects that would shorten the lifetime of effective minority carriers could be reduced significantly. In the prior art, nobody has ever dreamed that by conducting the second heat treatment at a relatively low temperature of 700° C. to 750° C., the quantity of defects remaining after the RTA process should be reduced that significantly.

A secondary ion mass spectrometry (SIMS) measurement was carried out on those samples that were not subjected to the second heat treatment and those samples that were subjected to an additional heat treatment at 700° C. as the second heat treatment process step (c) to estimate As and B profiles in the depth direction. The results are shown in FIG. 7.

As can be seen from FIG. 7, no matter whether the additional heat treatment was carried out at 700° C. or not, the As and B profiles hardly changed. That is to say, even if the additional heat treatment was carried out at 700° C., As and B caused thermal diffusion very little, and the junction depth did not change, thus never interfering with the device formation at all. In other words, by implanting As and B, performing a high-temperature activating RTA process, and then carrying out an FA process at 700° C., the dopants can be activated sufficiently with diffusion of As and B minimized, and yet the defects created during the implantation can be repaired.

A secondary ion mass spectrometry (SIMS) measurement was carried out on those samples that were not subjected to the additional heat treatment by omitting the process step (c) and those samples that were subjected to an additional heat treatment at 900° C. as the second heat treatment process step (c) to estimate As and B profiles in the depth direction. The results are shown in FIG. 8.

As can be seen from FIG. 8, if the heat treatment was carried out at 900° C., B diffused slightly and the junction depth changed a little. If the heat treatment were conducted at more than 900° C., then B would diffuse remarkably. In order to reduce the diffusion of B as much as possible, the second heat treatment is suitably carried out at a temperature of at most 800° C., and more suitably at a temperature of 750° C. or less. By setting the temperature of the second heat treatment within the range of 700° C. to 750° C., even if the FA process is carried out so as to change the temperature at a relatively low temperature rise/fall rate of 4° C./min to 10° C./min, for example, the diffusion of the dopants introduced can be reduced sufficiently and semiconductor devices with little dispersion in their characteristic can be manufactured with good reproducibility.

It should be noted that in this description, the temperature of the heat treatment is a value obtained by measuring the temperature in the heat treatment chamber with a thermocouple.

To sum up, according to this example in which the second heat treatment process step (c) was carried out, the defects could be reduced more significantly with the diffusion of the dopants still minimized, compared to the comparative example in which the second heat treatment process step (c) was not carried out.

According to an embodiment of the present disclosure, when a CCD image sensor is being fabricated, the first and second heat treatments are carried out right after dopant ions have been implanted to form the charge transfer section. Thus, a CCD image sensor with a small number of defects can be fabricated. As a result, the sensitivity characteristic and charge transfer efficiency of the CCD image sensor can be improved and the number of image defects can be reduced.

### INDUSTRIAL APPLICABILITY

By adopting the heat treatment method of the present disclosure, the dopants implanted can be activated sufficiently with their diffusion minimized using the same heat treatment system as the one that has been used in a conventional semiconductor device manufacturing process. In addition, according to an embodiment of the present disclosure, the crystal imperfections created during the dopant implantation can also be repaired, and therefore, a solid-state image sensor with excellent sensitivity characteristic, charge transfer efficiency and image quality is realized easily at a reduced cost. Furthermore, a manufacturing process according to such an embodiment of the present disclosure can also be used to form a channel region and source and drain regions of a MOSFET for use in an LSI so that little leakage current will flow through those channel and source and drain regions.

### REFERENCE SIGNS LIST

1 Si substrate
2 Si epitaxial grown film
3 gate insulating film
4 photoelectrically converting section
4(n) n-type region
4(p) p-type region
5 charge transfer section
5(n) n-type region
5(p) p-type region
6 device isolation region
7 charge extracting section
8 transfer electrode
9 interlevel dielectric film
10 opaque film
11 planarizing film
12 color filter
13 top lens
14 Si substrate
15 SiO₂ film
16 n-type dopant implanted layer
17 p-type dopant implanted layer

1. A method for fabricating a semiconductor device, the method comprising the steps of:
(a) implanting dopant ions into a semiconductor base member which is made of single-crystal Si to define at least one of an n-type region and a p-type region in the semiconductor base member;
(b) conducting a first heat treatment on the semiconductor base member, in which the n-type or p-type region has been defined, at a temperature rise/fall rate of 40° C./sec or more and with the highest temperature to reach set within the range of 1000° C. to 1200° C.; and
(c) conducting a second heat treatment on the semiconductor base member, which has gone through the first heat treatment, at a lower temperature rise/fall rate than in the first heat treatment and at a heat treatment temperature of 700° C. to 750° C.

2. The method of claim 1, wherein the step (a) includes the step of implanting at least two kinds of dopant ions into the semiconductor base member to define the n-type and p-type regions in the semiconductor base member.

3. The method of claim 1, wherein the second heat treatment is conducted at a temperature rise/fall rate of 40° C./sec or less.

4. The method of claim 1, wherein the semiconductor device is a solid-state image sensor.

5. The method of claim 3, wherein the second heat treatment is conducted at a temperature rise/fall rate of 4° C./min to 10° C./min.0.

6. The method of claim 2, wherein the second heat treatment is conducted at a temperature rise/fall rate of 40° C./sec or less.

7. The method of claim 2, wherein the semiconductor device is a solid-state image sensor.

8. The method of claim 3, wherein the semiconductor device is a solid-state image sensor.
